(19) United States
(12) Patent Application Publication
(10) Pub. No.: US 2025/0212655 A1
(43) Pub. Date: Jun. 26, 2025

(54) DISPLAY APPARATUS

(71) Applicant: LG Display Co., Ltd., Seoul (KR)

(72) Inventors: Giyoun KIM, Paju-si (KR); Jungwoo LEE, Paju-si (KR)

(21) Appl. No.: 18/792,247

(22) Filed: Aug. 1, 2024

(30) Foreign Application Priority Data
Dec. 22, 2023 (KR) 10-2023-0189294

(51) Int. Cl. H10K 59/80; H10K 59/12; H10K 77/10; H10K 102/00

(52) U.S. Cl. CPC H10K 59/873; H10K 59/1201; H10K 77/111; H10K 2102/311; H10K 2102/351

(57) ABSTRACT

A display apparatus may include a display panel, a cover layer disposed on the display panel, a film layer disposed on the cover layer, a coating layer disposed on the film layer, a transparent adhesive layer between the display panel and the cover layer, and a transparent resin layer disposed between the cover layer and the film layer. A thickness of the transparent resin layer may be different from a thickness of the transparent adhesive layer.

### CROSS-REFERENCE TO RELATED APPLICATION

The application claims the benefit of and priority to Korea Patent Application No. 10-2023-0189294 filed in the Republic of Korea on Dec. 22, 2023, the entirety of which is incorporated herein by reference for all purposes.

### BACKGROUND

### Technical Field

The present disclosure generally relates to a display apparatus, and more particularly, but not exclusively, to a flexible display apparatus.

### Description of the Related Art

As the information society develops, various demands for display apparatuses for displaying images are increasing, and various types of display apparatuses such as liquid crystal display (LCD) apparatuses and organic light emitting diode (OLED) display apparatuses are utilized.

Among the display apparatuses, there is an advantage in that the OLED display apparatus as the self-luminous types have superior viewing angle and contrast ratio than the LCDs, and are lighter and thinner and have low power consumption because they do not require a separate backlight. In addition, there is an advantage in that the OLED display apparatus may drive at a low direct current voltage, have a fast response speed, and especially low manufacturing costs. In current display apparatuses, external impacts can cause layers of the display to “lift” or separate, thus resulting in distorted image quality and/or damage to the display apparatus. Accordingly, it would be advantageous to have a display apparatus that overcomes the deficiencies and disadvantages of current solutions.

### BRIEF SUMMARY

The OLED display apparatuses may include a cover layer for protecting a display panel, and the cover layer may include glass or plastic. When the cover layer is formed of glass, a film layer, etc., may be further disposed on the cover layer to prevent the glass from shattering upon an external impact.

An aspect of the present disclosure is directed to providing a display apparatus in which lifting between a coupling layer and a film layer caused by an external impact can be minimized or durability against cracks of a cover layer can be minimized.

An aspect of the present disclosure is directed to providing a display apparatus in which external visibility of a groove caused by an external impact can be increased and display quality can be improved.

An aspect of the present disclosure is directed to providing a display apparatus having excellent adhesion between the cover layer and the film layer.

An aspect of the present disclosure is directed to providing a thin film display apparatus in which the thickness of a coupling member for coupling members of an upper structure can be reduced.

A display apparatus according to one or more embodiments of the present disclosure may include a display panel, a cover layer disposed on the display panel, a film layer disposed on the cover layer, a transparent adhesive layer between the display panel and the cover layer, and a transparent resin layer disposed between the cover layer and the film layer. A thickness of the transparent resin layer may be different from a thickness of the transparent adhesive layer.

According to various embodiments of the present disclosure, a method of manufacturing a display apparatus may include obtaining a display panel, disposing a cover layer on the display panel, disposing a film layer on the cover layer, disposing a transparent adhesive layer between the display panel and the cover layer, and disposing a transparent resin layer between the cover layer and the film layer, including forming the transparent resin layer by inkjet printing a transparent resin material on the cover layer.

A display apparatus according to one or more embodiments of the present disclosure may include a display panel including a folding area, a first non-folding area at a first side of the folding area, and a second non-folding area at a second side of the folding area different from the first side of the folding area, a cover layer disposed on the display panel, a film layer disposed on the cover layer, a transparent adhesive layer disposed between the display panel and the cover layer, and a transparent resin layer disposed between the cover layer and the film layer. A modulus of the transparent resin layer may be different from a modulus of the transparent adhesive layer.

A display apparatus according to one or more embodiments of the present disclosure may include a display panel, a transparent adhesive layer on the display panel, a cover layer having a glass material on the transparent adhesive layer, a transparent resin layer on the cover layer, and a film layer having a polymer organic material on the cover layer.

According to some embodiments of the present disclosure, the transparent resin may be disposed between the cover layer for protecting the display panel and the film layer for protecting the cover layer. The transparent resin may have a smaller thickness than the coupling member such as a transparent adhesive for coupling other members of the display apparatus and have a greater modulus. Therefore, according to some embodiments of the present disclosure, by minimizing the deformation of the light transparent resin even when the external impact is caused by the pointed object on the upper portion of the display device, it is possible to minimize the occurrence of the lifting between the film layer and the coupling layer caused by the external force or the cracks of the cover layer.

According to some embodiments of the present disclosure, it is possible to increase the appearance visibility of the display apparatus and improve the display quality.

In addition, since the deformation of the transparent resin can be minimized even when the external force is generated by the pointed object on the upper portion of the display apparatus, thereby minimizing the occurrence of the lifting or cracks caused by the corresponding external force, it is possible to provide the display apparatus with increased durability and increased lifetime.

In addition, since the transparent resin having the small thickness is disposed between the cover layer for protecting the display panel and the film layer for protecting the cover layer, it is possible to implement the display apparatus having the small thickness.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the present disclosure. Nothing in this section should be taken as a limitation on the present disclosure. Further aspects and advantages are discussed below in conjunction with aspects of the disclosure.

It is to be understood that both the foregoing background and the following description are non-limiting and are intended to provide further explanation of the inventive concepts of the disclosure, rather than to limit the disclosure.

### BRIEF DESCRIPTION OF THE SEVERAL VIEWS OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a perspective view of a display apparatus in a flat or resting state according to an embodiment of the present disclosure.

FIG. 2 is an elevational view of the display apparatus shown in FIG. 1 in a folded state.

FIG. 3 is a cross-sectional view of the display apparatus along line I-I′ in FIG. 1.

FIG. 4 is a schematic view showing a first experimental example of the present disclosure.

FIG. 5 is a cross-sectional view of a display apparatus according to an embodiment of the present disclosure.

FIGS. 6 to 8 are views showing a method of manufacturing a display apparatus according to embodiments of the present disclosure.

FIG. 9 is a schematic view showing a second experimental example of the present disclosure.

FIG. 10 is an elevational view of a second sample of a third experimental example of the present disclosure.

FIG. 11 is a cross-sectional view of a display panel of the display apparatus of FIG. 3.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete, to assist those skilled in the art to understand the inventive concepts without limiting the protected scope of the present disclosure.

For the expression that an element (e.g., layer, film, region, component, section, or the like) is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

It is understood that, although the terms “first,” “second,” or the like may be used herein to describe various elements (e.g., layers, films, regions, components, sections, members, parts, regions, areas, portions, steps, operations, and/or the like), these elements should not be limited by these terms, for example, to any particular order, sequence, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

Spatially relative terms, such as “below,” “beneath,” “lower,” “on,” “above,” “upper” and the like, may be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, may include all directions of “above” and “below.” Likewise, an above term “above” or “on” may include both directions of “above” and “below.”

When the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise.

Features of various embodiments of the present disclosure may be partially or overall coupled to or combined with each other, and may be variously inter-operated with each other and driven technically as those skilled in the art may sufficiently understand. The embodiments of the present disclosure may be carried out independently from each other, or may be carried out together in co-dependent relationship.

In the following description, various example embodiments of the present disclosure are described in detail with reference to the accompanying drawings. In addition, for convenience of description, a scale, dimension, size, and thickness of each of the elements illustrated in the accompanying drawings may be different from an actual scale, dimension, size, and thickness, and thus, embodiments of the present disclosure are not necessarily limited to a scale, dimension, size, and thickness illustrated in the drawings. In some embodiments, the drawings are to scale and features of the drawings can be relied on as additional disclosure regarding the structure, features, and functionality of the display apparatuses discussed herein.

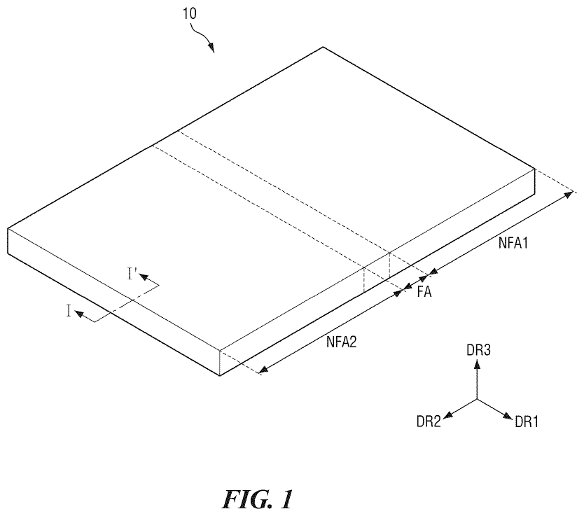

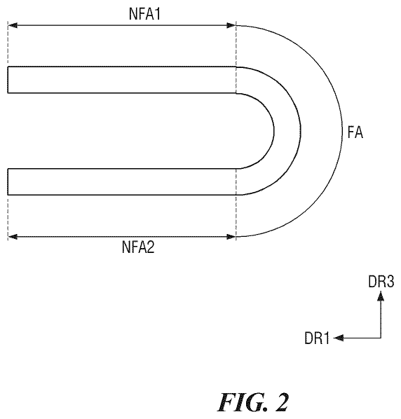

FIG. 1 is a perspective view of a display apparatus 10 in a flat or resting state according to an embodiment of the present disclosure. FIG. 2 is an elevational view showing the display apparatus 10 in a folded state according to an embodiment of the present disclosure.

Referring to FIGS. 1 and 2, the display apparatus 10 according to an embodiment of the present disclosure may be a foldable display apparatus. The display apparatus 10 may include a folding area FA extending in a first direction DR1, a first non-folding area NFA1 disposed at one side of the folding area FA in a second direction DR2, and a second non-folding area NFA2 disposed at the other side of the folding area FA in the second direction DR2. The folding area FA may have a longer dimension in the direction DR1 and a shorter dimension in the direction DR2.

As shown in FIG. 2, the display apparatus 10 may be folded with respect to or in the folding area FA. For example, when the display apparatus 10 is folded, the first non-folding area NFA1 and the second non-folding area NFA2 may be disposed to overlap each other in a thickness direction with the non-folding areas NFA1, NFA2 facing each other.

However, embodiments of the present disclosure are not limited thereto, and the display apparatus 10 may be a stretchable display apparatus or a bendable display apparatus. In the present disclosure, the stretchable display apparatus may be referred to as a display apparatus capable of displaying images even when bent or stretched. The foldable display apparatus and the stretchable display apparatus may have higher flexibility than general display apparatuses. A shape of the stretchable display apparatus may be freely changed according to a user's manipulation, for example, by bending or stretching the stretchable display apparatus. For example, when the user holds and pulls an end of the stretchable display apparatus, the stretchable display apparatus may be stretched by the user's force. Alternatively, when the user arranges the stretchable display apparatus on an uneven wall, the stretchable display apparatus may be disposed to be bent along a shape of a surface of the wall. In addition, when the force applied by the user is removed, the stretchable display apparatus may restore to its original state (or shape).

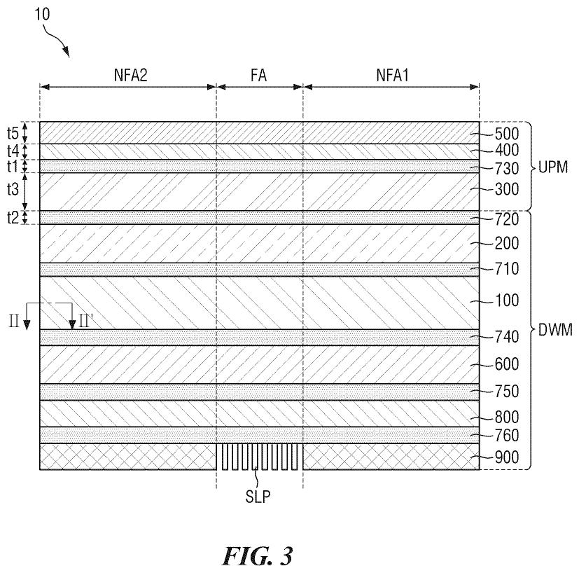

FIG. 3 is a cross-sectional view of the display apparatus 10 along line I-I′ in FIG. 1.

Referring to FIG. 3, the display apparatus 10 according to an embodiment of the present disclosure may include a lower structure DWM and an upper structure UPM disposed on the lower structure DWM.

The lower structure DWM may include a display panel 100, a polarization layer 200, a back-plate layer 600, a first plate layer 800, and a second plate layer 900. The display panel 100, the polarization layer 200, the back-plate layer 600, the first plate layer 800, and the second plate layer 900 may be represented by members, for example, a display member, a polarization member, a back-plate member, a first plate member, and a second plate member, or other like terms, such as layers, components, and the like, but embodiments of the present disclosure are not limited thereto.

The display panel 100 may include a plurality of pixels disposed at or in a display area of a base substrate and driving parts disposed at or in a non-display area around the display area to drive the pixels.

The pixels may include transistors TFTs connected to the driving parts with control signal lines, and a light emitting element OLED connected to the transistors TFTs.

The transistors TFT are turned on or off according to control signals applied through the control signal lines to adjust an amount of current applied to the light emitting element OLED.

The light emitting element OLED may emit light with luminance corresponding to the amount of current applied through the transistors TFT. The light emitting element OLED may include an organic light emitting diode, but embodiments of the present disclosure are not limited thereto.

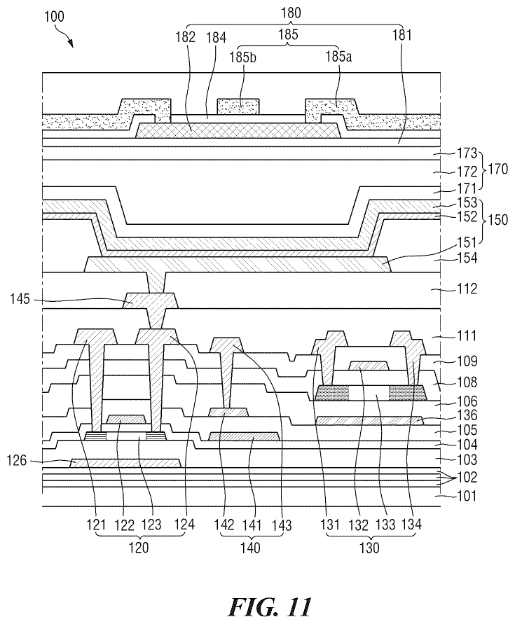

The base substrate may include a flexible substrate. For example, the base substrate may be an insulating plastic substrate one of polyimide, polyethersulfone, polyethylene terephthalate, and polycarbonate, but embodiments of the present disclosure are not limited thereto. Because the base substrate of the display panel 100 includes a flexible substrate, the display apparatus 10 may be implemented as a foldable, stretchable, or bendable display apparatus, but embodiments of the present disclosure are not limited thereto. Additional details of the display panel 100 are provided with reference to FIG. 11.

The back-plate layer 600 may be disposed under the display panel 100 and may be referred to as a back plate 600. The back-plate layer 600 may be disposed under the display panel 100 to support the display panel 100. The back-plate layer 600 may include a material capable of supporting the display panel 100. For example, the back-plate layer 600 may include polyethylene terephthalate (PET), polyimide (PI), or polycarbonate (PC), but embodiments of the present disclosure are not limited thereto. The back-plate layer 600 may constantly maintain a curvature of the display panel 100 when the display apparatus 10 is folded and suppress wrinkles occurring on an upper surface of the display panel 100. The polarization layer 200 may be disposed above the display panel 100. The polarization layer 200 may polarize light emitted from the display panel 100 at a polarization angle. The polarization layer 200 may emit light polarized at the polarization angle to an outside. The polarization layer 200 may include a function of blocking the reflection of light excluding the light polarized at the polarization angle among external light.

Plate layers 800 and 900 may be disposed under the back-plate layer 600. The plate layers 800 and 900 may include the first plate layer 800 and the second plate layer 900 disposed under the first plate layer 800. Each of the plate layers 800 and 900 may include a metal. For example, each of the plate layers 800 and 900 may include a stainless steel, but embodiments of the present disclosure are not limited thereto.

The second plate layer 900 may include patterns SLP disposed at the folding area FA. The first plate layer 800 may be disposed on the second plate layer 900, thereby preventing the patterns SLP from being visible. In other words, the first plate layer 800 may not include patterns SLP. For example, the pattern SLP may be disposed to correspond to the folding area FA. The pattern SLP may improve a folding performance of the display apparatus by allowing the second plate layer 900 at the folding area to be easily folded and easily restored to its original state after folding. For example, the patterns SLP may be disposed to be spaced apart from each other at a certain interval (or a distance). The pattern SLP may be an opening pattern, but embodiments of the present disclosure are not limited thereto. In an embodiment, the pattern SLP is a series of protrusions or ridges separated by spaces or openings that extend through a thickness of the second plate layer 900. The openings assist with the flexibility of the second plate layer 900 by allowing the region including the protrusions to ridges to more easily expand or contract. For example, when the non-folding areas NFA1, NFA2 are folded downwards about the folding area, the protrusions or ridges collapse or compress together to eliminate the spaces or openings. The absence of material in the openings or spaces relieves stress at the folding location and allows the second plate layer 900 to be more flexible in this region.

The polarization layer 200 may include a first phase retardation layer, a second phase retardation layer disposed on the first phase retardation layer, and a polarization layer disposed on the second phase retardation layer in sequential order and in direct contact with each other or separated by adhesive layers. In FIG. 3, although an example in which the polarization layer 200 and the display panel 100 are separated from each other is shown, embodiments of the present disclosure are not limited thereto, and the polarization layer 200 may be included in or as part of the display panel 100.

The lower structure DWM may further include coupling layers or adhesive layers configured to couple (or connect) members 100, 200, 600, 800, and 900. The lower structure DWM may include a first coupling layer 710, a second coupling layer 720, a fourth coupling layer 740, a fifth coupling layer 750, and a sixth coupling layer 760.

The first coupling layer 710 may be disposed between the display panel 100 and the polarization layer 200. The first coupling layer 710 may connect or couple to the display panel 100 and the polarization layer 200.

The second coupling layer 720 may be disposed between the polarization layer 200 and the cover layer 300. The second coupling layer 720 may connect or couple to the polarization layer 200 and the cover layer 300.

The fourth coupling layer 740 may be disposed between the back-plate layer 600 and the display panel 100. The fourth coupling layer 740 may connect or couple to the backplate layer 600 and the display panel 100.

The fifth coupling layer 750 may be disposed between the back-plate layer 600 and the first plate layer 800. The fifth coupling layer 750 may connect or couple to the back-plate layer 600 and the first plate layer 800.

The sixth coupling layer 760 may be disposed between the first plate layer 800 and the second plate layer 900. The sixth coupling layer 760 may connect or couple to the first plate layer 800 and the second plate layer 900.

The first coupling layer 710, the second coupling layer 720, the fourth coupling layer 740, the fifth coupling layer 750, and the sixth coupling layer 760 may each include a transparent adhesive. For example, the transparent adhesive may be a transparent resin (OCR) or a transparent adhesive (OCA). In an embodiment of the present disclosure, the first coupling layer 710, the second coupling layer 720, the fourth coupling layer 740, the fifth coupling layer 750, and the sixth coupling layer 760 may each include the transparent adhesive (OCA).

A thickness t2 of the second coupling layer 720 may be about 50 μm or more. The thickness t2 of the second coupling layer 720 may be a thickness of the transparent adhesive (OCA) included in the second coupling layer 720. In some embodiments, when the thickness t2 of the second coupling layer 720 is smaller than about 50 μm, the stress generated when the cover layer 300 is folded, stretched, or bent results in the second coupling layer 720 being deformed. In some embodiments, properties of the second coupling layer 720 allow for a thickness t2 of less than about 50 μm without deforming the second coupling layer 720.

A modulus (e.g., a storage modulus or an elastic modulus) of the second coupling layer 720 may be in a range of about 1 kPa to about 100 kPa. When the modulus of the second coupling layer 720 is smaller than about 10 kPa, a material in the second coupling layer 720 may flow when the second coupling layer 720 is formed, and thus a punching yield of the second coupling layer 720 may be reduced. For example, when the modulus of the second coupling layer 720 is low, an end of the second coupling layer 720 may be deformed during punching, resulting in poor appearance and an unpeeled release material. When the modulus of the second coupling layer 720 exceeds about 100 kPa, the cover layer 300 cannot relieve the stress generated during folding, stretching, or bending, and thus the second coupling layer 720 may be deformed. Future developments or other changes to the second coupling layer 720 may allow for the modulus of the second coupling layer 720 to be less than about 10 kPa without deforming. Preferably, for purposes of this disclosure, the modulus of the second coupling layer 720 is about 10 kPa to about 100 kPa. Except as otherwise noted, the relative term “about” means plus or minus 5% of the stated value or characteristic.

The upper structure UPM may include the cover layer 300.

The cover layer 300 may be disposed on the polarization layer 200. The cover layer 300 may be formed of glass or formed of a glass material including quartz. The cover layer 300 may be disposed on the display panel 100 to protect the members (e.g., the lower structure DWM) disposed under the cover layer 300 from the outside. Since the display apparatus 10 may be implemented as a foldable, stretchable, or bendable display apparatus, the cover layer 300 should preferably have a flexibility. And thus, the modulus (e.g., Young's modulus or elastic modulus) of the cover layer 300 may be 70 GPa or less, and a thickness t3 of the cover layer 300 may be about 100 μm or less. However, when the thickness t3 of the cover layer 300 is too small, the members disposed under the cover layer 300 may not be adequately protected, and thus the cover layer 300 may, for example, preferably have a thickness of at least about 20 μm. Changes to the cover layer 300 and/or future developments may enable the thickness t3 of the cover layer 300 to be less than about 20 μm while adequately protecting the display apparatus or the display panel. The cover layer 300 may be a cover layer formed by chemical reinforcement, but embodiments of the present disclosure are not limited thereto. The cover layer 300 may be a cover window, a window cover, or a cover member. The embodiments of the present disclosure are not limited thereto.

The cover layer 300 can protect the members disposed under the cover layer 300 from the outside, but as described above, since the cover layer 300 is formed of a glass material, the cover layer 300 is damaged by an external force, creating glass fragments. The glass fragments may shatter to the outside of the display apparatus 10. According to an embodiment of the present disclosure, to prevent the shattering of the glass fragments due to the damage to the cover layer 300 or increase the durability of the cover layer 300, another layer may be further included on the cover layer 300. For example, a film layer 400 and a coating layer 500 may be further included on the cover layer 300.

The film layer 400 may protect the cover layer 300. The film layer 400 may be a thin film sheet formed of a polymer organic material. The film layer 400 may have a high transmittance of 88% or more, heat resistance of 100° C. or more, and a coefficient of thermal expansion of 80×10⁻⁶/K or less, but embodiments of the present disclosure are not limited thereto. Therefore, the film layer 400 may not be deteriorated in a high temperature and high humidity or a thermal impact environment (e.g., within 100° C.), and it is possible to prevent damage to the film layer 400. For example, the film layer 400 may be formed of a material having a low coefficient of thermal expansion and thermal stability. For example, the film layer 400 may be formed of polyimide (PI), (poly) norbornene, high heat-resistant polyethylene terephthalate (PET), epoxy, urethane, etc., but embodiments of the present disclosure are not limited thereto. For another example, the film layer 400 may be formed of a co-polymer. For example, the film layer 400 may be formed of a copolymer combining polymethyl methacrylate (PMMA) with PMMA, a copolymer combining polycarbonate (PC) with PI, a copolymer combining PMMA with PI, or a copolymer combining urethane, but embodiments of the present disclosure are not limited thereto. The thickness t4 of the film layer 400 may be about 150 μm or less, but the embodiments of the present disclosure are not limited thereto. When the thickness t4 of the film layer 400 exceeds 150 μm, the display apparatus 10 is less flexible than is desired for implementation as the foldable, stretchable, or bendable display apparatus. When the thickness t4 of the film layer 400 is about 25 μm or more, the cover layer 300 can be protected. For example, when the thickness 14 of the film layer 400 is about 25 μm or more, it is possible to prevent physical destruction of the cover layer 300 and even when the cover layer 300 is destroyed or damaged to generate glass fragments, prevent the shattering of the glass fragments to the outside. In an embodiment, the film layer 400 may exceed 150 μm with changes to the material composition or other characteristics of the film layer 400.

The coating layer 500 may be disposed on the film layer 400. The coating layer 500 may be formed by being coated on an upper surface of the film layer 400. Thus, the coating layer 500 and the film layer 400 are in direct contact in some embodiments. Since the coating layer 500 allows a front surface of the cover layer 300 to perform a touch function, the coating layer 500 may be implemented as a surface protection layer having more reinforced strength. When the coating layer 500 is formed as the surface protection layer, the coating layer 500 may be formed of a resin with relatively high hardness when cured, such as an acrylic resin, an epoxy resin, or a silicone-based compound, among others. Further, the coating layer 500 may have an anti-finger (AF) or anti-reflective (AR) function as needed. The coating layer 500 may be implemented by synthesizing the resin having such a function or implemented by forming various patterns, for example, a pattern such as moth eye. The coating layer 500 may be a hard coating layer, but embodiments of the present disclosure are not limited thereto. The third coupling layer 730 may be disposed between the cover layer 300 and the film layer 400. The third coupling layer 730 may couple or connect the cover layer 300 with the film layer 400. The third coupling layer 730 may include a same material as the first coupling layer 710, the second coupling layer 720, and the fourth coupling layer 740, but embodiments of the present disclosure are not limited thereto.

On an upper portion of the display apparatus 10 according to one embodiment of the present disclosure, physical deformation may occur in the components of the display apparatus 10 due to an external pointed object.

When the pointed object presses an upper surface of the display apparatus 10 with a predetermined force, physical deformation may occur in the third coupling layer 730. For example, an air gap may be formed at an interface between the third coupling layer 730 and the film layer 400.

The thickness t1 of the third coupling layer 730 may be about 50 μm or more. The thickness t1 of the third coupling layer 730 may be a thickness of the transparent adhesive (OCA) included in the third coupling layer 730. A modulus (e.g., a storage modulus) of the third coupling layer 730 may be in a range of about 10 kPa to about 100 kPa.

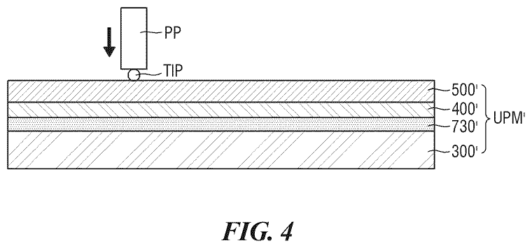

Therefore, since the thickness t1 of the third coupling layer 730 is large and the modulus is relatively small, when the pointed object presses the upper surface of the display apparatus 10 with the predetermined force, the third coupling layer 730 having a large thickness t1 and a small modulus may be deformed physically. The film layer 400 is lifted from the third coupling layer 730 due to the pressing of the third coupling layer 730 caused by the physical deformation of the third coupling layer 730 to form the air gap at the interface between the third coupling layer 730 and the film layer 400. The corresponding air gap may be visible from the outside, resulting in poor appearance or poor display quality of the display apparatus 10 and affecting the durability of the display apparatus 10, and thus, the lifetime of the display apparatus 10 may be reduced. In addition, when the pointed object is pressed with a greater force, cracks may occur in the cover layer 300 disposed under the third coupling layer 730. Therefore, in the first experimental example of FIG. 4, the thickness of the third coupling layer 730 of FIG. 3 was configured to be smaller, and the modulus (e.g., the storage modulus) was configured to be larger.

FIG. 4 is a schematic view showing a first experimental example of the present disclosure.

The first experimental example of FIG. 4 is an experiment for checking points at which the lifting of a film layer 400′ from a third coupling layer 730′ among an upper structure UPM′ (which includes layers 300′, 730′, 400′, and 500′) and cracks of the upper structures 300′, 730′, 400′, and 500′ may occur.

When a pointed object PP is pressed on the upper surface of the display apparatus 10 with the predetermined force, the points at which the lifting and cracks of the layers of the upper structure UPM′ occurred were checked. A tip portion TIP may be formed on an end portion of the pointed object PP, and the tip portion TIP may have a diameter of, for example, 300 μm to 1,000 μm, but embodiments of the present disclosure are not limited thereto.

The first experimental example of the present disclosure was measured in a compression mode and was conducted under the condition in which the diameter of the end portion TIP of the pointed object PP that applied a force to the upper surface of the upper structure in the compression mode was in a range of 0.2 mm to 1 mm, and a force of 0.25 kgf was gradually increased from the point at which the end portion TIP of the pointed object PP was in contact with the surface of the coating layer 500′, and the lifting of the film layer 400′ was observed by an optical microscope. For example, the lifting of the film layer 400′ may be observed by the optical microscope when the film layer 400′ is lifted by about 80 μm or more from the third coupling layer 730′.

A first sample may be an upper structure including the cover layer 300′ having the thickness of 90 μm, the third coupling layer 730′ having the thickness of 5 μm, the film layer 400′ having the thickness of 30 μm, and the coating layer 500′ having the thickness of 40 μm that are disposed sequentially. A modulus (e.g., a Young's modulus or elastic modulus) of the cover layer 300′ is 70 GPa or less, a modulus (e.g., a storage modulus or elastic modulus) of the third coupling layer 730′ is in a range of 50 kPa to 500 kPa, and a modulus (e.g., a Young's modulus or clastic modulus) of the film layer 400′ is in a range of 2 GPa to 8 GPa. The third coupling layer 730′ is formed of a transparent resin (OCR). The thicknesses and modulus of the layers configured in the first sample do not limit the content of the present disclosure.

A second sample may be an upper structure including the cover layer 300′ having the thickness of 90 μm, the third coupling layer 730′ having the thickness of 8 μm, the film layer 400′ having the thickness of 30 μm, and the hard coating layer 500′ having the thickness of 40 μm that are disposed sequentially. The modulus of the cover layer 300′ is 70 GPa or less, the modulus of the third coupling layer 730′ is in a range of 50 kPa to 500 kPa, and the modulus of the film layer 400′ is in a range of 2 GPa to 8 GPa. The third coupling layer 730′ may be formed of a transparent resin (OCR). The thicknesses and modulus of the layers configured in the second sample do not limit the content of the present disclosure.

A third sample may be an upper structure including the cover layer 300′ having the thickness of 90 μm, the third coupling layer 730′ having the thickness of 15 μm, the film layer 400′ having the thickness of 30 μm, and the hard coating layer 500′ having the thickness of 40 μm that are disposed sequentially. The modulus of the cover layer 300′ is 70 GPa or less, the modulus of the third coupling layer 730′ is in a range of 1 kPa to 100 kPa, and the modulus of the film layer 400′ is in a range of 2 GPa to 8 GPa. The third coupling layer 730′ may be formed of a transparent adhesive (OCA). The thicknesses and moduli of the layers configured in the third sample do not limit the content of the present disclosure.

A fourth sample may be an upper structure including the cover layer 300′ having the thickness of 90 μm, the third coupling layer 730′ having the thickness of 25 μm, the film layer 400′ having the thickness of 30 μm, and the hard coating layer 500′ having the thickness of 40 μm that are disposed sequentially. The modulus of the cover layer 300′ is 70 GPa or less, the modulus of the third coupling layer 730′ is in a range of 1 kPa to 100 kPa, and the modulus of the film layer 400′ is in a range of 2 GPa to 8 GPa. The third coupling layer 730′ is formed of a transparent adhesive (OCA). The thicknesses and modulus of the layers configured in the fourth sample do not limit the content of the present disclosure.

In the first sample, it was confirmed that when the pointed object PP was applied to the upper structures 300′, 730′, 400′, and 500′ with a force of 1.5 kgf or more, the film layer 400′ was lifted from the upper surface of the third coupling layer 730′. Upon measurement using the optical microscope, when the film layer 400′ is lifted from the upper surface of the third coupling layer 730′, an image of a white dot may be visible. The generated dots may cause the poor appearance visibility of the display apparatus. In addition, in the first sample, it was confirmed that when the pointed object PP was applied to the upper structures 300′, 730′, 400′, and 500′ with a force of 5.25 kgf or more, cracks occurred in the cover layer 300′.

In the second sample, it was confirmed that when the pointed object PP was applied to the upper structures 300′, 730′, 400′, and 500′ with a force of 1.5 kgf or more, the film layer 400′ was lifted from the upper surface of the third coupling layer 730′. In addition, in the second sample, it was confirmed that when the pointed object PP was applied to the upper structures 300′, 730′, 400′, and 500′ with a force of 5.00 kgf or more, cracks occurred in the cover layer 300′.

In the third sample, it was confirmed that when the pointed object PP was applied to the upper structures 300′, 730′, 400′, and 500′ with a force of 0.75 kgf or more, the film layer 400′ was lifted from the upper surface of the third coupling layer 730′. In addition, in the third sample, it was confirmed that when the pointed object PP was applied to the upper structures 300′, 730′, 400′, and 500′ with a force of 4.25 kgf or more, cracks occurred in the cover layer 300′.

In the fourth sample, it was confirmed that when the pointed object PP was applied to the upper structures 300′, 730′, 400′, and 500′ with a force of 0.5 kgf or more, the film layer 400′ was lifted from the upper surface of the third coupling layer 730′. In addition, in the fourth sample, it was confirmed that when the pointed object PP was applied to the upper structures 300′, 730′, 400′, and 500′ with a force of 4.00 kgf or more, cracks occurred in the cover layer 300′.

As a result of the first experimental example of the present disclosure, it was confirmed that the first and second samples in which the third coupling layers 730′ had thicknesses of 5 μm and 8 μm used or required 0.75 kgf and 1.0 kgf more force before the film layer 400′ was lifted or separated from the third coupling layer 730′ than the third and fourth samples in which the third coupling layers 730′ had larger thicknesses of 15 μm and 25 μm. Therefore, it was confirmed that as the thickness of the third coupling layer 730′ was smaller, the deformation of the third coupling layer 730′ caused by an external force was less or more force was required to cause deformation. In addition, it was confirmed that the first sample having a smaller thickness than the second sample and the third sample having a smaller thickness than the fourth sample used or required larger forces before the film layer 400′ was lifted from the third coupling layer 730′ than the second and fourth samples, respectively, and thus it was confirmed that even when the display apparatus includes the third coupling layer 730′, as the thickness of the third coupling layer 730′ becomes smaller or decreases, the third coupling layer 730′ was less deformed or more force was required to cause deformation. It was confirmed that the reason why the first and second samples used 0.75 kgf and 1.0 kgf greater forces before the film layer 400′ was lifted from the third coupling layer 730′ than the third and fourth samples was that the moduli of the third coupling layers 730′ of the first and second samples were greater than the modulus of the third coupling layer 730′ of each of the third and fourth samples. Therefore, since the modulus of the third coupling layer 730′ is large, it can be seen that a relatively large force is required to lift the film layer 400′ from the third coupling layer 730′, thereby increasing the durability of the display apparatus. The experiment confirmed that the thickness is related to the modulus, and thus smaller thicknesses of the third coupling layer 730′ resulted in layers with a higher modulus that were better adapted to resisting deformation or could withstand more force before deformation occurred.

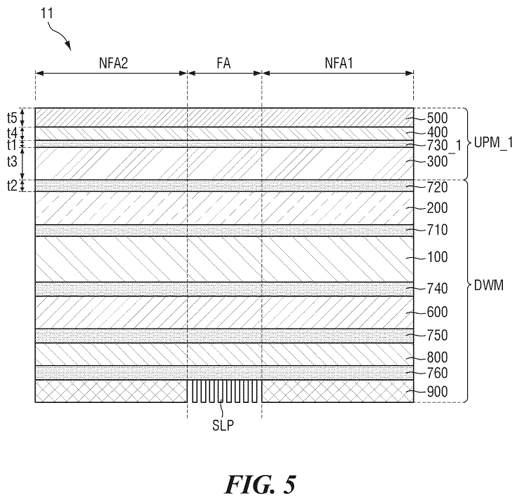

Therefore, when the third coupling layer 730′ was formed of a transparent resin (OCR), the modulus was in a range of 50 kPa to 500 kPa, and the thickness was 10 μm or less (e.g., in a range of 5 μm to 8 μm), the occurrence of cracks caused by the impact of the external pointed object could be prevented, and the third coupling layer 730′ was less deformed. An embodiment thereof will be described with reference to FIG. 5.

FIG. 5 is a cross-sectional view of a display apparatus 11 according to one or more embodiments of the present disclosure.

Referring to FIG. 5, a display apparatus 11 according to another embodiment of the present disclosure may include a third coupling layer 730_1 of an upper structure UPM_1.

A thickness t1 of the third coupling layer 730_1 according to one or more embodiments of the present disclosure may be about 10 μm or less. Since the thickness t1 of the third coupling layer 730_1 is set to about 10 μm or less, it is possible to minimize the physical deformation of the third coupling layer 730_1. Therefore, lifting (or peeling or delamination or separation) from the third coupling layer 730_1 of the film layer 400 may not occur.

In some embodiments, when the thickness t1 of the third coupling layer 730_1 is too small, the cover layer 300 and the film layer 400 may not be well coupled or bonded by the third coupling layer 730_1. Therefore, the adhesiveness of the third coupling layer 730_1 may be very low given that the layer is too thin to sufficiently couple the film layer 400 and the third coupling layer 730_1. Therefore, the thickness t1 of the third coupling layer 730_1 may preferably be about 5 μm or more.

The thickness t4 of the film layer 400 of the display apparatus 11 according to one or more embodiments of the present disclosure may be about 30 times or less the thickness t1 of the third coupling layer 730_1. For example, the film layer 400 may be formed of transparent polyimide (CPI), but embodiments of the present disclosure are not limited thereto. For example, the thickness t4 of the film layer 400 may be about 75 μm or less. Since the thickness of the film layer 400 is about 30 times or less the thickness t1 of the third coupling layer 730_1, as described in FIG. 4, when the pointed object may press the upper surface of the display apparatus 10 with a predetermined force, the film layer 400 may not absorb all of the forces applied by the pointed object, thereby causing the film layer 400 to be lifted from the third coupling layer 730_1. To solve such a problem, the storage modulus (or elastic modulus) of the third coupling layer 730_1 may be configured to be greater than the modulus of the second coupling layer 720. For example, the modulus of the third coupling layer 730_1 may be in a range of about 50 kPa to about 500 kPa, but embodiments of the present disclosure are not limited thereto. Since the storage modulus (or elastic modulus) of the third coupling layer 730_1 is configured to be about 50 kPa or more, the third coupling layer 730_1 may absorb and dissipate all of the forces applied by the pointed object. Since the storage modulus (or elastic modulus) of the third coupling layer 730_1 is about 500 kPa or less, flexibility may be provided to the third coupling layer 730_1 so that the display apparatus 11 may be implemented as a foldable, stretchable, or bendable display apparatus.

The modulus (e.g., Young's modulus or clastic modulus) of the film layer 400 may be smaller than the modulus (e.g., Young's modulus) of the cover layer 300 and may be greater than the modulus (e.g., the storage modulus or clastic modulus) of the third coupling layer 730. For example, the modulus of the film layer 400 may be 2 GPa or more. For example, the modulus of the film layer 400 may be in a range of 2 GPa to 8 GPa, but embodiments of the present disclosure are not limited thereto. For example, since the modulus of the film layer 400 is 8 GPa or less, flexibility may be provided to the film layer 400 so that the display apparatus 10 may be implemented as a foldable, stretchable, or bendable display apparatus.

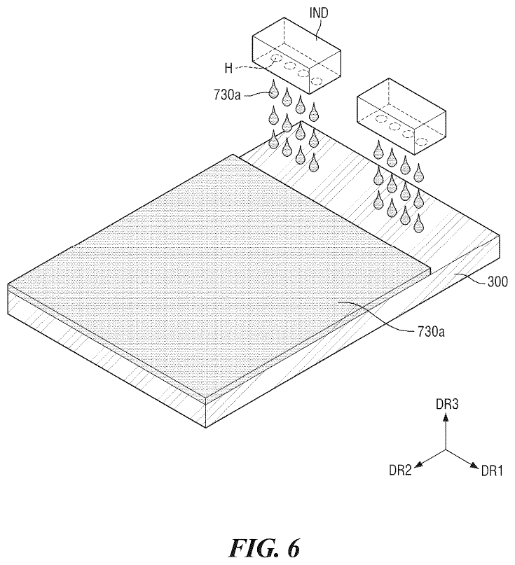

Since the thickness t1 of the third coupling layer 730_1 according to one or more embodiments of the present disclosure is configured to be in a range of about 5 μm to about 10 μm or less, it can be seen that the occurrence of cracks caused by the impact of an external pointed object may be further reduced. The present disclosure also contemplates methods for forming the third coupling layer 730_1 with a relatively small thickness t1 on the cover layer 300. For example, the display apparatus 11 may be formed with the thin third coupling layer 730_1 through an inkjet printing device IND (see FIG. 6).

FIGS. 6 to 8 are views showing a method of manufacturing a display apparatus, such as display apparatus 11, according to one or more embodiments of the present disclosure. Referring to FIG. 6, a transparent resin material 730a may be applied on the cover layer 300 through an inkjet printing object IND. A plurality of holes H are formed in a head of the inkjet printing device IND. The transparent resin material 730a may be sprayed onto the cover layer 300 through the holes H of the head of the inkjet printing device IND. To form the thickness t1 of the third coupling layer 730_1 described in FIG. 5 to about 5 μm to about 10 μm or less, the volume of the transparent resin material 730a sprayed through each hole H may be in a range of about 8 pL to about 15 pL. The holes H of the head may have a size corresponding to the volume of the transparent resin material 730a. For example, the holes H of the head may have the size corresponding to the volume of the transparent resin material 730a having about 8 pL to about 15 pL. In some embodiments, when the holes H of the head have a very fine size, as is preferred, the transparent resin materials 730a sprayed through each hole H agglomerate with each other and thus are not sprayed well, or an attractive force may be generated between the transparent resin material 730a and the hole H, and thus the transparent rein material 730a may not be well sprayed.

The transparent resin material 730a may have a viscosity of about 7 cps (centipoise) to about 18 cps at about 25° C. to about 45° C. When the transparent resin material 730a has a viscosity of about 12 cps or more at about 25° C. to about 45° C., the transparent resin material 730a sprayed through the hole H may not flow on the cover layer 300. Thus, it is preferable that the transparent resin material 730a has a viscosity of about 12 cps or less at about 25° C. to about 45° C. When the transparent resin material 730a has such a viscosity, a phenomenon in which the transparent resin material 730a agglomerates with each other through each hole H and is not sprayed or a phenomenon in which the transparent resin material 730a is not sprayed due to the generation of the attractive force generated between the holes H may not occur. Accordingly, it is preferred that the transparent resin material 730a be prepared to have a viscosity of about 12 cps or less at about 25° C. to about 45° C., although viscosities of about 7 cps to about 18 cps at about 25° C. to about 45° C. may be sufficient in some embodiments, among others.

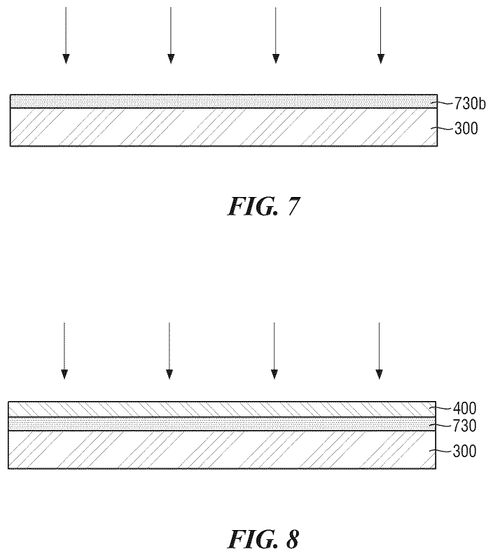

Referring to FIG. 7, the transparent resin material 730a (see FIG. 7) applied on the cover layer 300 may be primarily cured. The primary curing may be ultraviolet light UV (marked by arrow) curing. The primary curing may be semi-curing. For example, a curing rate of the primary curing may be in a range of about 70% to about 85% of the final hardness of a fully cured resin material 730a. When the curing rate of the primary curing is about 70% or less, in the process of arranging the film layer 400 to be described below in FIG. 8 on the transparent resin material 730b of FIG. 7, the transparent resin material 730b may flow, thereby causing defects such as flowing to side surfaces of the cover layer 300. In case that the curing rate of the primary curing is about 85% or more, when the film layer 400 to be described below in FIG. 8 is disposed on the transparent resin material 730b of FIG. 7, a bonding strength between the film layer 400 and the transparent resin material 730b may be reduced relative to a less cured sample. The experiment for the bonding strength will be described with reference to FIG. 9.

Subsequently, referring to FIG. 8, the film layer 400 may be disposed on the transparent resin material 730b of FIG. 8 and then secondarily cured to form the transparent resin layer 730. A curing rate of the secondary curing may be about 90% or more. The secondary curing may be UV curing.

In the present specification, although an example in which the primary and secondary curing are UV curing is described, but embodiments of the present disclosure are not limited thereto, and the primary and secondary curing may also be thermal curing or other types of curing and may occur in one or more steps.

FIG. 9 is a schematic view showing a second experimental example of the present disclosure relating to bonding strength.

In the second experimental example of FIG. 9, the bonding strength between the third coupling layer 730′ and a base BP was measured by coupling the base BP under the third coupling layer 730′, coupling a backing film PF on the third coupling layer 730′, and changing the base BP for each third coupling layer 730′ (hereinafter referred to as fifth to eighth samples) of each of the first to fourth samples described in FIG. 5. The second experimental example was measured in a tensile mode, and the bonding strength between the third coupling layer 730′ and the base BP was measured while a jig pulls an end portion of the backing film PF upward (marked by arrow) (measured in the tensile mode, and 180° peel test measurement was conducted). The base BP includes a glass material formed of the same material as the cover layer 300 formed under the film layer 400 of FIG. 8 or a base film formed of the same material as the film layer 400. For example, the material of the film layer 400 may be CPI (transparent polyimide base), but embodiments of the present disclosure are not limited thereto. The backing film PF was etched polyethylene terephthalate (PET), and a peeling rate of the backing film PF from the third coupling layer 730′ was set to 5 mm/sec.

As a result of the second experimental example of the present disclosure, in a fifth sample, a bonding strength with the glass base was measured to be 0.5 kgf/inch, and a bonding strength with the film base was measured to be 0.6 kgf/inch. In a sixth sample, a bonding strength with the glass base was measured to be 1.1 kgf/inch, and a bonding strength with the film base was measured to be 1.0 kgf/inch. In a seventh sample, a bonding strength with the glass base was measured at 1.3 kgf/inch, and a bonding strength with the film base was measured to be 1.1 kgf/inch. In an eighth sample, a bonding strength with the glass base was measured to be 1.6 kgf/inch, and a bonding strength with the film base was measured to be 1.3 kgf/inch.

As a result of the second experimental example of the present disclosure, it can be seen that the greater the thicknesses of the third coupling layers 730′ of the fifth to eighth samples, the stronger the bonding strength with the base BP. Even in the case of the fifth sample having the smallest thickness, a bonding strength with the glass base was measured to be 0.5 kgf/inch, and a bonding strength with the film base was measured to be 0.6 kgf/inch. A bonding strength with the glass base and the bonding strength with the film base that are each 0.5 kgf/inch or more is determined to be a sufficient bonding strength for the intended application of the display apparatus. Thus, it can be seen that the fifth and sixth samples maintain a good or sufficient bonding state with the base BP even though the thickness of the third coupling layer 730′ is smaller than about 10 μm compared to the seventh and eighth samples with larger thicknesses of the third coupling layer 730′.

As a result of the second experimental example, to increase the bonding strength with the CPI base, which is the base BP, the curing rate of the primary curing of the transparent resin layer 730 described in FIGS. 6 to 8 may be set to about 85% or more.

Referring to FIG. 5 together, according to one or more embodiments of the present disclosure, the bonding strength between the third coupling layer 730_1 and the cover layer 300 may be in a range of about 0.5 kgf/inch to about 1.1 kgf/inch. The bonding strength between the third coupling layer 730_1 and the film layer 400 may be in a range of about 0.6 kgf/inch to about 1.0 kgf/inch. Since the bonding strength between the third coupling layer 730_1 and the cover layer 300 is about 0.5 kgf/inch or more, and the bonding strength between the third coupling layer 730_1 and the film layer 400 is about 0.6 kgf/inch or more, when the display apparatus 11 is folded, stretched, or bent, the cover layer 300 and/or the film layer 400 are not peeled off from the third coupling layer 730_1, and the bonding or attachment state with the third coupling layer 730_1 may be maintained.

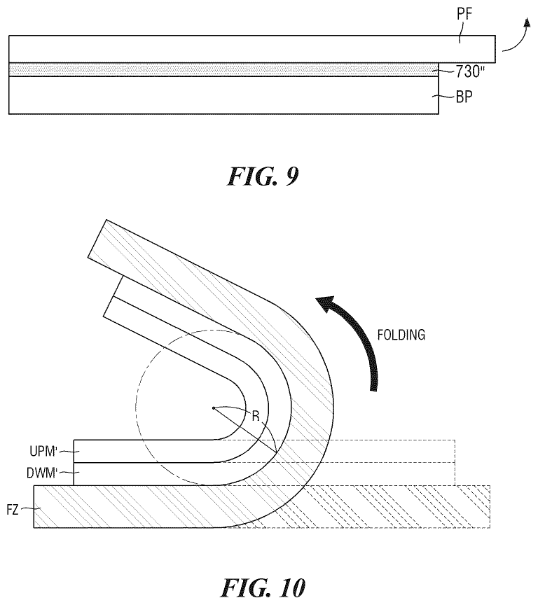

FIG. 10 is a cross-sectional view of a second sample of a third experimental example of the present disclosure.

Referring to FIG. 10, the third experimental example was conducted after arranging a lower structure DWM′ under the upper structure UPM′ of FIG. 5. The lower structure DWM′ may include the same components as the lower structure DWM of FIG. 3. In the third experiment, after the mutually coupled lower structure DMW′ and upper structure UPM′ are fastened to a folding jig FZ having the radius of curvature R of 5 R (or 5 mm), as shown in FIG. 10, the folding of the lower structure DMP′ and the upper structure UPM′ may be repeated. In the third experimental example of the present disclosure, a folding cycle may be 1 Hz. The appearance of the lower structure DMP′ and the upper structure UPM′ was observed every 10 k (10,000) folding times. The first to fourth samples of FIG. 10 are the same as the first to fourth samples of FIG. 6.

As a result of the third experimental example of the present disclosure, in the first sample, the appearance defect occurred at a folding count of 50 k. The appearance defect may be a defect in which the film layer 400′ is lifted (or peeled off) from the third coupling layer 730′. In the second sample, the appearance defect occurred at a folding count of 100 k (100,000 times). In the third sample, the appearance defect occurred at a folding count of 90 k. In the fourth sample, the appearance defect occurred at a folding count of 100 k. Therefore, it can be seen that the appearance defect occurs in the second and fourth samples when the folding count increases compared to the first and third samples. It can be seen that the second and fourth samples having the thicknesses of the third coupling layers 730′ that are relatively greater than that of each of the first and third samples have durability even when folded.

FIG. 11 is a cross-sectional view of the display panel 100 of FIG. 3 along line II-II′ in FIG. 3.

The display panel 100 may include a substrate 101, a first thin film transistor 120, a second thin film transistor 130, a light emitting part 150 or light emitting layer 150, an encapsulation part 170 or encapsulation layer 170, and a touch part 180 or touch sensor array 180.

The substrate 101 may include one or more plastic materials. For example, the substrate 101 may be a multi-substrate including a plurality of plastic materials such as polyimide, but embodiments of the present disclosure are not limited thereto.

The buffer layer 102 may be disposed on the substrate 101. The buffer layer 102 may minimize or reduce the diffusion of moisture or oxygen permeating the substrate 101. The buffer layer 102 may be formed by alternately stacking silicone nitride (SiNx) and silicone oxide (SiOx) at least once, but embodiments of the present disclosure are not limited thereto.

A first light blocking layer 126 may be disposed on the buffer layer 102. The first light blocking layer 126 can prevent light from being transmitted through a first semiconductor layer 123 of the first thin film transistor 120. For example, the first semiconductor layer 123 may be disposed to overlap the first light blocking layer 126. The first light blocking layer 126 may include a single layer or multiple layers formed of any one of molybdenum (Mo), aluminum (Al), chromium (Cr), nickel (Ni), neodymium (Nd), and copper (Cu) or an alloy thereof, but embodiments of the present disclosure are not limited thereto.

A first insulating layer 103 may be disposed on the first light blocking layer 126. The first insulating layer 103 may prevent a short between a component of the first thin film transistor 120 and the first light blocking layer 126 and the buffer layer 102. The first insulating layer 103 may be formed of the same material as the buffer layer 102, but embodiments of the present disclosure are not limited thereto. For example, the first insulating layer 103 may be formed of an inorganic material, such as silicone nitride (SiNx) or silicone oxide (SiOx), but embodiments of the present disclosure are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicone-based semiconductor material, such as amorphous silicone or polycrystalline silicone, but embodiments of the present disclosure are not limited thereto. The first semiconductor layer 123 may include a channel area, a source area, and a drain area.

Since the polycrystalline semiconductor layer has higher mobility than the amorphous semiconductor layer and the oxide semiconductor layer, power energy consumption may be low and reliability can be excellent. Therefore, the driving transistor may be formed of the polycrystalline semiconductor layer, among other options.

A second insulating layer 104 may be disposed on the first semiconductor layer 123. The second insulating layer 104 may be formed of the same material as the first insulating layer 103 and may prevent a short between the first semiconductor layer 123 and another component of the first thin film transistor 120.

A first gate electrode 122 may be disposed on the second insulating layer 104. The first gate electrode 122 may be disposed on the second insulating layer 104 to overlap the channel area of the first semiconductor layer 123. The first gate electrode 122 may include a single layer or multiple layers formed of molybdenum (Mo), copper (Cu), titanium (Ti), aluminum (Al), chromium (Cr), gold (Au), nickel (Ni), neodymium (Nd), or an alloy thereof, but embodiments of the present disclosure are not limited thereto. The first gate electrode 122 may be disposed together with the gate lines.

A third insulating layer 105 may be disposed on the first gate electrode 122. The third insulating layer 105 may be formed of the same material as the first insulating layer 103 or the second insulating layer 104.

The first source electrode 121 and the first drain electrode 124 may be disposed on the third insulating layer 105.

The first source electrode 121 and the first drain electrode 124 may be electrically connected to the first semiconductor layer 123 through contact holes. The first source electrode 121 and the first drain electrode 124 may be formed of a metal material. For example, the first source electrode 121 and the first drain electrode 124 may include a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but embodiments of the present disclosure are not limited thereto.

The first source electrode 121 and the first drain electrode 124 may be disposed together with data lines. For example, the data line may be formed of the same material as the first source electrode 121 and the first drain electrode 124 and may be formed coplanarly therewith, but embodiments of the present disclosure are not limited thereto.

The storage electrode 140 may be disposed to be spaced apart from the first thin film transistor 120. The storage electrode 140 may include a first storage electrode 141, a second storage electrode 142, and a third storage electrode 143.

The first storage electrode 141 may be formed of the same material as the first gate electrode 122 and may be formed coplanarly therewith, but embodiments of the present disclosure are not limited thereto.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance. The second storage electrode 142 may be formed of the same material as the first storage electrode 141, but embodiments of the present disclosure are not limited thereto.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light blocking layer 136 may be disposed coplanarly with the second storage electrode 142.

The second light blocking layer 136 can prevent light directed to the second semiconductor layer 133 similar to the first light blocking layer 126, thereby extending the lifetime of the second thin film transistor 130. For example, the second semiconductor layer 133 may be disposed to overlap the second light blocking layer 136.

A fourth insulating layer 106 may be disposed on the second light blocking layer 136. The fourth insulating layer 106 may be formed of the same material as the first insulating layer 103, the second insulating layer 104, or the third insulating layer 105, but embodiments of the present disclosure are not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicone-based semiconductor material, such as amorphous silicone or polycrystalline silicone, but embodiments of the present disclosure are not limited thereto.

A fifth insulating layer 108 may be disposed on the second semiconductor layer 133. The fifth insulating layer 108 may be formed of the same material as the first insulating layer 103, the second insulating layer 104, the third insulating layer 105, or the fourth insulating layer 106, but embodiments of the present disclosure are not limited thereto.

A second gate electrode 132 may be disposed on the fifth insulating layer 108.

The second gate electrode 132 may be formed of the same material as the first gate electrode 122. For example, the second gate electrode 132 may include a single layer or multiple layers formed of molybdenum (Mo), copper (Cu), titanium (Ti), aluminum (Al), chromium (Cr), gold (Au), nickel (Ni), neodymium (Nd), or an alloy thereof, but embodiments of the present disclosure are not limited thereto.

A sixth insulating layer 109 may be disposed on the second gate electrode 132. The sixth insulating layer 109 may be formed of the same material as the first insulating layer 103, the second insulating layer 104, the third insulating layer 105, the fourth insulating layer 106, or the fifth insulating layer 108, but embodiments of the present disclosure are not limited thereto.

The first source electrode 121, the first drain electrode 124, the third storage electrode 143, the second source electrode 131, and the second drain electrode 134 may be disposed on the sixth insulating layer 109.

The third storage electrode 143, the second source electrode 131, and the second drain electrode 134 may be formed of the same material as the first source electrode 121 and the first drain electrode 124 and disposed coplanarly therewith. For example, the third storage electrode 143, the second source electrode 131, and the second drain electrode 134 may include a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but embodiments of the present disclosure are not limited thereto.

The first thin film transistor 120 may be a driving transistor, and the second thin film transistor 130 may be a switching transistor, but embodiments of the present disclosure are not limited thereto.

A first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be formed of an organic material. For example, the first protective layer 111 may be formed of an organic material containing an acrylic resin, an epoxy resin, a phenolic resin, a polyamide resin, or a polyimide resin, but embodiments of the present disclosure are not limited thereto.

A second protective layer 112 may be disposed on the first protective layer 111. The second protective layer 112 may be formed of the same material as the first protective layer 111, but embodiments of the present disclosure are not limited thereto.

A connection electrode 145 may be disposed between the first protective layer 111 and the second protective layer 112.

The connection electrode 145 may electrically connect the first thin film transistor 120 with the light emitting part 150. The connection electrode 145 may be formed of the same material as the first source electrode 121 and the first drain electrode 124, but embodiments of the present disclosure are not limited thereto.

The connection electrode 145 may include a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but embodiments of the present disclosure are not limited thereto.

The light emitting part 150 or light emitting assembly 150 may be disposed on the second protective layer 112. The light emitting part 150 may include an anode electrode 151, an organic layer 152, and a cathode electrode 153.

The anode electrode 151 may be disposed on the second protective layer 112. The anode electrode 151 may be electrically connected to the first thin film transistor 120 through a contact hole formed in the second protective layer 112. The anode electrode 151 may be a reflective electrode that reflects light, but embodiments of the present disclosure are not limited thereto. The anode electrode 151 may include a metal material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy, and may include a single layer or multiple layers, but embodiments of the present disclosure are not limited thereto.

The organic layer 152 may be disposed on the anode electrode 151. The organic layer 152 may include one or more light emitting structures (or light emitting elements or elements) stacked on the anode electrode 151 in the order or reverse order of a hole transport layer and an electron transport layer. The organic layer 152 may be an organic light emitting layer, an inorganic light emitting layer, a quantum dot light emitting layer, a micro light emitting diode, a micro mini light emitting diode, or the like, but embodiments of the present disclosure are not limited thereto. For example, the organic layer 152 of the display panel 100 according to one embodiment of the present disclosure may include the organic light emitting layer. The organic layer 152 may include a red light emitting layer, a green light emitting layer, and a blue light emitting layer. The organic layer 152 may be a white light emitting layer, but embodiments of the present disclosure are not limited thereto.

The cathode electrode 153 may be disposed on the organic layer 152. The cathode electrode 153 may be a transparent electrode that reflects light, but embodiments of the present disclosure are not limited thereto. For example, the cathode electrode 153 may include a transparent conductive material, such as indium tin oxide (ITO) or indium zinc oxide (IZO), or a metal that transmits visible light.

The bank 154 may be disposed to expose the anode electrode 151. The bank 154 may define an opening (or a light emitting area) of the sub-pixel and may be disposed to cover an edge portion of the anode electrode 151. Each sub-pixel may include a red light emitting area, a green light emitting area, and a blue light emitting area. For example, the sub-pixel may be a pixel, but is not limited by the term.

The encapsulation part 170 or encapsulation layer 170 may be disposed on the bank 154 or the light emitting part 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material, but embodiments of the present disclosure are not limited thereto.

The touch sensor array 180 may include a touch buffer layer 181 that may be disposed on the encapsulation part 170. For example, the touch buffer layer 181 may be disposed on the third encapsulation layer 173. The touch buffer layer 181 may be formed of the same material as the buffer layer 102, but embodiments of the present disclosure are not limited thereto. The touch sensor array 180 further includes a touch insulating layer 184 that may be disposed on the touch buffer layer 181. The touch insulating layer 184 may prevent a short between the touch electrodes. The touch insulating layer 184 may be formed of silicone oxide (SiOx), silicone nitride (SiNx), or multiple layers thereof, but embodiments of the present disclosure are not limited thereto. The touch sensor array 180 further includes a first touch electrode 185 that may be disposed on the touch insulating layer 184. The first touch electrode 185 may include a 1a touch electrode 185a extending in a first direction and a 1b touch electrode 185b extending in a second direction that differs from the first direction.

A second touch electrode 182 of the touch sensor array 180 may be disposed between the touch buffer layer 181 and the touch insulating layer 184.

The second touch electrode 182 may be electrically connected to the 1a touch electrode 185a through a contact hole formed in the touch insulating layer 184. For example, the 1a touch electrode 185a and the second touch electrode 182 may extend in the first direction.

The first touch electrode 185 and the second touch electrode 182 may include a metal material. For example, the first touch electrode 185 and the second touch electrode 182 may be formed of titanium (Ti), nickel (Ni), aluminum (Al), or an alloy thereof, and may be formed of three layers such as titanium (Ti)/aluminum (Al)/titanium (Ti), but embodiments of the present disclosure are not limited thereto.

A display apparatus according to various embodiments of the present disclosure may be described or summarized as follows.

A display apparatus according to various embodiments of the present disclosure may include a display panel, a cover layer disposed on the display panel, a film layer disposed on the cover layer, a transparent adhesive layer between the display panel and the cover layer, and a transparent resin layer disposed between the cover layer and the film layer. A thickness of the transparent resin layer may be different from a thickness of the transparent adhesive layer.

According to various embodiments of the present disclosure, the thickness of the transparent resin layer may be 10 μm or less.

According to various embodiments of the present disclosure, a thickness of the film layer may be 30 times or less the thickness of the transparent resin layer.

According to various embodiments of the present disclosure, a storage modulus of the transparent resin layer may be different from a storage modulus of the transparent adhesive layer.

According to various embodiments of the present disclosure, the storage modulus of the transparent resin layer may be in a range of 50 kPa to 500 kPa. The storage modulus of the transparent adhesive layer may be in a range of 1 kPa to 100 kPa.

According to various embodiments of the present disclosure, a storage modulus of the film layer may be greater than the storage modulus of the transparent adhesive layer. The storage modulus of the film layer may be in a range of 2 GPa to 8 GPa.

According to various embodiments of the present disclosure, a bonding strength between the transparent resin layer and the cover layer may be in a range of 0.5 kgf/inch to 1.1 kgf/inch. A bonding strength between the transparent resin layer and the film layer may be in a range of 0.6 kgf/inch to 1.0 kgf/inch.

According to various embodiments of the present disclosure, a method of manufacturing a display apparatus may be summarized as including: obtaining a display panel; disposing a cover layer on the display panel; disposing a film layer on the cover layer; disposing a transparent adhesive layer between the display panel and the cover layer; and disposing a transparent resin layer between the cover layer and the film layer, including forming the transparent resin layer by inkjet printing a transparent resin material on the cover layer.

According to various embodiments of the present disclosure, disposing the transparent resin material may include spraying the transparent resin material onto the cover layer through a hole of a head of an inkjet printing device, and spraying a volume of the transparent resin material from the hole in a range of 8 pL to 15 pL.

According to various embodiments of the present disclosure, disposing the transparent resin layer may include the transparent resin material having a viscosity in a range of 7 cps to 18 cps at 25° C. to 45° C.

According to various embodiments of the present disclosure, disposing the transparent resin layer may include applying the transparent resin material on the cover layer and curing the transparent resin material at a first instance to form a primarily cured transparent resin material, and disposing the film layer may include disposing the film layer on the primarily cured transparent rein material.

According to various embodiments of the present disclosure, curing the transparent resin material at the first instance may include curing the transparent resin material at a curing rate in a range of 70% to 85%, the method further including, after disposing the film layer on the primarily cured transparent resin material, curing the primarily cured transparent resin material at a second instance to form the transparent resin layer.

A display apparatus according to various embodiments of the present disclosure may include a display panel including a folding area, a first non-folding area at a first side of the folding area, and a second non-folding area at a second side of the folding area different from the first side of the folding area, a cover layer disposed on the display panel, a film layer disposed on the cover layer, a transparent adhesive layer disposed between the display panel and the cover layer, and a transparent resin layer disposed between the cover layer and the film layer. A storage modulus of the transparent resin layer may be different from a storage modulus of the transparent adhesive layer.

According to various embodiments of the present disclosure, the storage modulus of the transparent resin layer may be in a range of 50 kPa to 500 kPa. The storage modulus of the transparent adhesive layer may be in a range of 1 kPa to 100 kPa.

According to various embodiments of the present disclosure, the storage modulus of the film layer may be greater than the storage modulus of the transparent adhesive layer. A storage modulus of the film layer may be in a range of 2 GPa to 8 GPa.

According to various embodiments of the present disclosure, a thickness of the transparent resin layer may be 10 μm or less.

According to various embodiments of the present disclosure, a thickness of the film layer may be 30 times or less the thickness of the transparent resin layer.

According to various embodiments of the present disclosure, the bonding strength between the transparent resin layer and the cover layer may be in a range of 0.5 kgf/inch to 1.1 kgf/inch. A bonding strength between the transparent resin layer and the film layer may be in a range of 0.6 kgf/inch to 1.0 kgf/inch.

A display apparatus according to various embodiments of the present disclosure may include a display panel, a transparent adhesive layer on the display panel, a cover layer having a glass material on the transparent adhesive layer, a transparent resin layer on the cover layer, and a film layer having a polymer organic material on the cover layer.

According to various embodiments of the present disclosure, the glass material may include quartz.

According to various embodiments of the present disclosure, the glass material may have a heat resistance of 100° C. or more.

According to various embodiments of the present disclosure, the glass material may have a coefficient of thermal expansion of 80×10⁻⁶/K or less.

It will be apparent to those skilled in the art that various modifications and variations may be made in the apparatus of the present disclosure without departing from the scope of the disclosure. Thus, it is intended that the present disclosure covers the modifications and variations of this disclosure that come within the scope of the claims and their equivalents.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a display panel;
a cover layer disposed on the display panel;
a film layer disposed on the cover layer;
a transparent adhesive layer disposed between the display panel and the cover layer; and
a transparent resin layer disposed between the cover layer and the film layer,
wherein a thickness of the transparent resin layer is different from a thickness of the transparent adhesive layer.

2. The display apparatus of claim 1, wherein the thickness of the transparent resin layer is 10 μm or less.

3. The display apparatus of claim 2, wherein a thickness of the film layer is 30 times or less the thickness of the transparent resin layer.

4. The display apparatus of claim 1, wherein a storage modulus of the transparent resin layer is different from a storage modulus of the transparent adhesive layer.

5. The display apparatus of claim 4, wherein the storage modulus of the transparent resin layer is in a range of 50 kPa to 500 kPa, and
wherein the storage modulus of the transparent adhesive layer is in a range of 1 kPa to 100 kPa.

6. The display apparatus of claim 4, wherein a storage modulus of the film layer is greater than the storage modulus of the transparent adhesive layer, and
wherein the storage modulus of the film layer is in a range of 2 kPa to 8 kPa.

7. The display apparatus of claim 1, wherein a bonding strength between the transparent resin layer and the cover layer is in a range of 0.5 kgf/inch to 1.1 kgf/inch, and
wherein a bonding strength between the transparent resin layer and the film layer is in a range of 0.6 kgf/inch to 1.0 kgf/inch.

8. A method of manufacturing a display apparatus, comprising:
obtaining a display panel;
disposing a cover layer on the display panel;
disposing a film layer on the cover layer;
disposing a transparent adhesive layer between the display panel and the cover layer; and
disposing a transparent resin layer between the cover layer and the film layer, including forming the transparent resin layer by inkjet printing a transparent resin material on the cover layer.

9. The method of claim 8, wherein disposing the transparent resin material includes spraying the transparent resin material onto the cover layer through a hole of a head of an inkjet printing device, and spraying a volume of the transparent resin material from the hole in a range of 8 pL to 15 pL.

10. The method of claim 8, wherein disposing the transparent resin layer includes the transparent resin material having a viscosity in a range of 7 cps to 18 cps at 25° C. to 45° C.

11. The method of claim 8, wherein disposing the transparent resin layer includes applying the transparent resin material on the cover layer and curing the transparent resin material at a first instance to form a primarily cured transparent resin material, and
wherein disposing the film layer includes disposing the film layer on the primarily cured transparent rein material.

12. The method of claim 11, wherein curing the transparent resin material at the first instance includes curing the transparent resin material at a curing rate in a range of 70% to 85%, the method further comprising, after disposing the film layer on the primarily cured transparent resin material:
curing the primarily cured transparent resin material at a second instance to form the transparent resin layer.

13. A display apparatus, comprising:
a display panel including a folding area, a first non-folding area on a first side of the folding area, and a second non-folding area on a second side of the folding area, wherein the second side is different from the first side of the folding area;
a cover layer disposed on the display panel;
a film layer disposed on the cover layer;
a transparent adhesive layer disposed between the display panel and the cover layer; and
a transparent resin layer disposed between the cover layer and the film layer,
wherein a storage modulus of the transparent resin layer is different from a storage modulus of the transparent adhesive layer.

14. The display apparatus of claim 13, wherein the storage modulus of the transparent resin layer is in a range of 50 kPa to 500 kPa, and
wherein the storage modulus of the transparent adhesive layer is in a range of 1 kPa to 100 kPa.

15. The display apparatus of claim 13, wherein a storage modulus of the film layer is greater than the storage modulus of the transparent adhesive layer, and wherein the storage modulus of the film layer is in a range of 2 GPa to 8 GPa.

16. The display apparatus of claim 13, wherein a thickness of the transparent resin layer is 10 μm or less.

17. The display apparatus of claim 14, wherein a thickness of the film layer is 30 times or less the thickness of the transparent resin layer.

18. The display apparatus of claim 13, wherein a bonding strength between the transparent resin layer and the cover layer is in a range of 0.5 kgf/inch to 1.1 kgf/inch, and a bonding strength between the transparent resin layer and the film layer is in a range of 0.6 kgf/inch to 1.0 kgf/inch.

19. A display apparatus, comprising:
a display panel;
a transparent adhesive layer on the display panel;
a cover layer having a glass material on the transparent adhesive layer;
a transparent resin layer on the cover layer; and
a film layer having a polymer organic material on the cover layer.

20. The display apparatus of claim 19, wherein the glass material comprises quartz.

21. The display apparatus of claim 19, wherein the glass material has a heat resistance of 100° C. or more.

22. The display apparatus of claim 19, wherein the glass material has a coefficient of thermal expansion of 80×10⁻⁶/K or less.
